(19) United States
(12) Patent Application Publication
(10) Pub. No.: US 2003/0157771 A1
(43) Pub. Date: Aug. 21, 2003

(54) Method of forming an ultra-thin gate dielectric by soft plasma nitridation

(76) Inventors: Tuung Luoh, Kaohsiung (TW); Hans Lin, Nantou (TW); Yaw-Lin Hwang, Taipei (TW)

Correspondence Address: POWELL, GO;DSTEIN, FRAZER & MURPHY LLP, P.O. BOX 97223, WASHINGTON, DC, 20090-7223, US

(21) Appl. No.: 10/077,795

(22) Filed: Feb. 20, 2002

(51) Int. Cl. H01L 21/336; H01L 21/31; H01L 21/469

(52) U.S. Cl. 438/287; 438/769; 438/771; 438/776

(57) ABSTRACT

A method of forming an ultra-thin gate dielectric by soft nitrogen-containing plasma. The method comprises a pre-nitridation step nitrifying a substrate surface by soft nitrogen-containing plasma, and a thermal oxidation step oxidizing the substrate surface to form an ultra-thin gate dielectric on the substrate surface. The plasma density of the soft nitrogen-containing plasma is about 10⁹-10¹³ cm⁻³.

### CROSS-REFERENCE TO RELATED APPLICATION

This application claims the priority benefit of Taiwan application serial no. [No.], filed [date], the full disclosure of which is incorporated herein by reference.

### BACKGROUND OF THE INVENTION

1. Field of Invention

The present invention relates to a method of manufacturing semiconductor devices. More particularly, the present invention relates to a method of forming an ultra-thin gate dielectric by soft nitrogen-containing plasma.

2. Description of Related Art

When the integrity of the semiconductor integrated circuit is larger, the need of an ultra-thin gate dielectric with high dielectric constant and low current leakage is also larger. When the semiconductor processes go into below the 0.18 μm, the thickness of the gate dielectric is decreased to less than 30-40 Å. The gate dielectric with thickness less than 30-40 Å is called an ultra-thin gate dielectric. Therefore, how to produce such an ultra-thin gate dielectric in such a limiting process window and gain good thickness uniformity in addition to better breakdown resistance is a problem needed to be urgently solved.

The dielectric constant of a gate oxide produced by conventional thermal oxidation is about 3.9, and it often has structural defects such as pin hole. The structural defects of the gate oxide cause problems of direct tunneling current, and therefore it cannot be used as an ultra-thin gate dielectric.

A method of controlling the thickness of the gate oxide is disclosed in U.S. Pat. No. 5,330,920. The nitrogen ions are directly implanted into the substrate surface layer, then a thermal oxidation is performed to form the gate oxide on the substrate. Another method is disclosed in U.S. Pat. No. 6,110,842. This patent uses high-density plasma to implant nitrogen ions into the selected area of a substrate, and then a thermal oxidation is performed to form the gate oxide on the substrate. The resulted gate oxide is thinner in areas that have been implanted nitrogen ions, and it is thicker in areas that without implanting nitrogen ions. But the substrate surface is directly impacted by plasma; therefore the surface structure of the substrate is injured. Furthermore, the kinetic energy of plasma arriving the substrate is larger, the implanted depth of nitrogen ions is also deeper. Therefore, an ultra-thin gate dielectric is not easily formed.

### SUMMARY OF THE INVENTION

It is therefore an objective of the present invention to provide a method of forming an ultra-thin gate dielectric by soft nitrogen-containing plasma.

It is another objective of the present invention to provide a method for retarding the oxidation rate of a substrate surface by soft nitrogen-containing plasma.

In accordance with the foregoing and other objectives of the present invention, this invention provides a method of forming an ultra-thin gate dielectric by soft nitrogen-containing plasma and then oxidizing the substrate surface. The method comprises a pre-nitridation step nitrifying a substrate surface by soft nitrogen-containing plasma, and a thermal oxidation step oxidizing the substrate surface to form an ultra-thin gate dielectric on the substrate surface.

The plasma density of the soft nitrogen-containing plasma is about 10⁹-10¹³ cm³. The gas used by the soft nitrogen-containing plasma comprises a nitrogen-containing gas. The flow rate of the nitrogen-containing gas is about 1-100 sccm.

The soft nitrogen-containing plasma can be generated either by remote or by decoupled way. When the remote plasma is used in the pre-nitridation step, the pre-nitridation step is performed under a temperature of about 0-650° C. and a pressure of about 0.001-5 torr for about 3-180 sec. When the decoupled plasma is used in the pre-nitridation step, the pre-nitridation step is performed under a temperature of about 0-100° C. and a pressure of about 0.001-0.5 torr for about 3-60 sec.

From the foregoing above, the substrate surface is uniformly nitrified by soft nitrogen-containing plasma to control the thickness of the gate dielectric in the later oxidation step. The method provided by this invention can solve the problems of substrate surface injured by directly implanting nitrogen ions into the substrate in the prior art.

It is to be understood that both the foregoing general description and the following detailed description are exemplary, and are intended to provide further explanation of the invention as claimed.

### DESCRIPTION OF THE PREFERRED EMBODIMENTS

In this invention, the substrate surface is uniformly nitrified by soft nitrogen-containing plasma to control the thickness of the gate dielectric in the later oxidation step, and the soft nitrogen-containing plasma can be generated either by remote way or by decoupled way.

When remote plasma is used in a nitridation reaction, the process is called remote plasma nitridation (RPN). RPN uses plasma containing nitrogen radical generated in a remote location from the wafer to undergo a nitridation reaction. Similarly, when decoupled plasma is used for nitridation reaction, the process is called decoupled plasma nitridation (DPN). DPN uses radio frequency (RF) to generate plasma containing nitrogen radical in a quasi-remote way.

If a silicon wafer is nitrified by soft nitrogen-containing plasma, network bondings of silicon nitride or silicon oxynitride are formed on the surface layer of the silicon wafer. If a thermal oxidation is successively performed, the oxidation rate of the silicon wafer is retarded to facilitate forming an ultra-thin gate dielectric.

Generally speaking, remote plasma nitridation uses microwave to interact with a nitrogen-containing gas to generate plasma containing nitrogen radical. After the plasma transported in a long path to contact with the silicon wafer, the kinetic energy of the plasma is almost zero. Then a nitridation reaction is processed under a temperature of about 0-650° C. and a pressure of about 0.001-5 torr. The reaction time of remote plasma nitridation is enough for about 3-180 sec.

Since the nitrogen radicals react with the silicon wafer only by diffusive contact, the injuring problem of the silicon wafer surface caused by directly impacting of nitrogen plasma in the prior art can be solved. The implanting depth of nitrogen ions by the remote plasma nitridation is also shallower and more uniform than direct nitrogen implanting method. These two factors are important for forming an ultra-thin gate dielectric.

Decoupled plasma nitridation generates plasma containing nitrogen radical in a quasi-remote way. Therefore, decoupled plasma has similar characteristics to the remote plasma. That is, the kinetic energy of the plasma produced by decoupled way is almost zero when the plasma reacts with the wafer, but the decoupled plasma nitridation can be processed under a much lower temperature and pressure then the remote plasma nitridation. The decoupled plasma nitridation is preferred to be processed under a temperature of 0-100° C. and a pressure of about 0.001-0.5 torr, and thus the production cost can be largely reduced.

The implanting depth of nitrogen ions by the decoupled plasma is also less than the remote plasma, and the nitrogen ions implanting profile is more easily controlled by the decoupled plasma. The reaction time of decoupled plasma nitridation is only about 3-60 sec, which is much less than that of the remote plasma nitridation, and thus the throughput can be largely increased. The typical reaction time of the decoupled plasma nitridation is about 30 sec. Furthermore, the process window of the decoupled plasma nitridation is also larger than that of the remote plasma nitridation, and thus the product yield can be also greatly increased.

Since the decoupled plasma nitridation generates plasma in a quasi-remote way, the injuring problem of the silicon wafer surface caused by directly impacting of nitrogen plasma in the prior art can be solved. The implanting depth of nitrogen ions by the decoupled plasma nitridation is shallower and more uniform than the remote plasma nitridation, and thus a thinner gate dielectric can be formed.

In both way of generating the soft nitrogen-containing plasma mentioned above, the nitrogen-containing gas can be N₂ or NH₃, and the flow rate can be 1-100 sccm. The nitrogen-containing gas can be mixed with an inert gas such as Ar, He or combinations thereof to generate the soft nitrogen-containing plasma, or it can be mixed with an oxygen-containing gas such as NO, N₂O, O₂ or combinations thereof to generate the soft nitrogen-containing plasma. The plasma density of decoupled plasma nitridation can be about 10⁹-10¹³ cm⁻³.

After nitrifying the substrate surface, a thermal oxidation step or in-situ steamed generation (ISSG) step can be used to oxidize the wafer surface to form an ultra-thin gate dielectric.

The ultra-thin gate dielectric formed by the method provided by this invention can trap hot electron to reduce the degradation of metal-oxide-semiconductor (MOS) transistor caused by hot electron degradation. Since the wafer surface has no structure injuring, the integrity of the gate dielectric can be largely increased to reduce the leakage current of the gate. Furthermore, the dielectric constant of the gate dielectric is increased because the gate dielectric contains nitrogen ions. Therefore, the equivalent oxide thickness (EOT) of the gate dielectric can be largely reduced, and the gate dielectric can be used in the 0.18 μm semiconductor process or even in the 0.10 μm semiconductor process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming an ultra-thin gate dielectric by soft nitrogen-containing plasma, the method comprising:
performing a pre-nitridation step to nitrify a substrate surface by soft nitrogen-containing plasma, a plasma density used in the soft nitrogen-containing plasma is about 10⁹-10¹³ cm⁻³; and
performing an oxidation step to oxidize the substrate surface to form a gate dielectric on the substrate surface.

2. The method of claim 1, wherein a gas source used by the soft nitrogen-containing plasma comprises a nitrogen-containing gas.

3. The method of claim 2, wherein the nitrogen-containing gas is selected from the group consisting of N₂, NH₃ and a combination thereof.

4. The method of claim 2, wherein a flow rate of the nitrogen-containing gas is about 1-100 sccm.

5. The method of claim 2, wherein the gas source used by the soft nitrogen-containing plasma further comprises an inert gas.

6. The method of claim 5, wherein the inert gas is selected from the group consisting of He, Ar and a combination thereof.

7. The method of claim 2, wherein the gas source used by the soft nitrogen-containing plasma further comprises an oxygen-containing gas.

8. The method of claim 7, wherein the oxygen-containing gas is selected from the group consisting of NO, N₂O, O₂ and a combination thereof.

9. The method of claim 1, wherein the soft nitrogen-containing gas comprises remote nitrogen-containing plasma.

10. The method of claim 9, wherein the pre-nitridation step is performed under a temperature of about 0-650° C.

11. The method of claim 9, wherein the pre-nitridation step is performed under a pressure of about 0.001-5 torr.

12. The method of claim 9, wherein the pre-nitridation step is performed for about 3-180 sec.

13. The method of claim 1, wherein the soft nitrogen-containing gas comprises decoupled nitrogen-containing plasma.

14. The method of claim 13, wherein the pre-nitridation step is performed under a temperature of about 0-100° C.

15. The method of claim 13, wherein the pre-nitridation step is performed under a pressure of about 0.001-0.5 torr.

16. The method of claim 13, wherein the pre-nitridation step is performed for about 3-60 sec.

17. A method for retarding the oxidation rate of a substrate surface by remote plasma nitridation, the method comprising:
nitrifying a substrate surface by remote plasma nitridation, the remote plasma nitridation using a nitrogen-containing gas to generate plasma and the density of the plasma being about 10⁹-10¹³ cm⁻³; and
oxidizing the substrate surface to form a gate dielectric by thermal oxidation.

18. The method of claim 17, wherein the nitrifying step is performed under a temperature of about 0-650° C. and a pressure of about 0.001-5 torr.

19. The method of claim 17, wherein the nitrifying step is performed for about 3-180 sec.

20. A method for retarding the oxidation rate of a substrate surface by decoupled plasma nitridation, the method comprising:
nitrifying a substrate surface by decoupled plasma nitridation, the decoupled plasma nitridation using a nitrogen-containing gas to generate plasma and the density of the plasma being about 10⁹-10¹³cm⁻³; and
oxidizing the substrate surface to form a gate dielectric by thermal oxidation.

21. The method of claim 20, wherein the nitrifying step is performed under a temperature of about 0-100° C. and a pressure of about 0.001-0.5 torr.

22. The method of claim 20, wherein the nitrifying step is performed for about 3-60 sec.
